(19) United States
(12) Patent Application Publication
(10) Pub. No.: US 2022/0155253 A1
(43) Pub. Date: May 19, 2022

(54) BIOSENSORS WITH CHARGE SENSING AND DEBYE SCREENING

(71) Applicant: Khyron Technologies, Inc., Goleta, CA (US)

(72) Inventors: Luke Theogarajan, Goleta, CA (US); Prajakta Kulkarni, Goleta, CA (US); David F. Meng, San Ramon, CA (US)

(21) Appl. No.: 17/521,647

(22) Filed: Nov. 8, 2021

Related U.S. Application Data
(60) Provisional application No. 63/114,839, filed on Nov. 17, 2020.

(51) Int. Cl. G01N 27/414; H01L 29/423

(52) U.S. Cl. CPC G01N 27/4145; G01N 27/4146; H01L 29/42316

(57) ABSTRACT

A system having a biosensor as well as a biomarker, a recognition motif, an anti-Debye screening layer, and a charge sensing layer. The biosensor can include the recognition motif, the anti-Debye screening layer, and the charge sensing layer. A method can implement the system to detect the biomarker using a combination of the recognition motif, the anti-Debye screening layer, and the charge sensing layer. A single device can include a recognition motif, an anti-Debye screening layer, and a charge sensing layer, and the recognition motif can receive a biomarker which allows the device to sense the biomarker. The system, method and device each can implement decoupled charge-based sensing and Debye screening.

### CROSS-REFERENCE TO RELATED APPLICATIONS

The present application claims the benefit of priority from U.S. Provisional Patent Application No. 63/114,839, filed on Nov. 17, 2020, and entitled “ELECTRONIC BIOSENSOR WITH DECOUPLED CHARGE BASED SENSING AND DEBYE SCREENING”, the entire disclosure of which application is hereby incorporated herein by reference.

### TECHNICAL FIELD

The present disclosure relates to biosensors. Specifically, the present disclosure relates to biosensors with charge sensing and Debye screening. For example, the present disclosure relates to biosensors with decoupled charge-based sensing and Debye screening.

### BACKGROUND

In general, a biosensor is an analytical device, used for the detection of a substance or a molecule, which combines a biological component with a transducer. The biological component (such as tissue, microorganisms, organelles, cell receptors, enzymes, antibodies, nucleic acids, etc.) interacts with, binds with, or recognizes an analyte under study and outputs a signal accordingly. The biological component can be naturally occurring or engineered. The transducer (which can be a physicochemical detector) transforms the outputted signal from the biological component into another signal (such as an electrical signal).

Often the transducer transduces one signal to another in a physicochemical way. Transducing can be optical, piezoelectric, electrochemical, and electrochemiluminescence, for example. And, the result from the transducer of the biosensor can include a product from the interaction of the analyte with the biological component. The result from the transducer of the biosensor can be measured and quantified.

Some biosensors can connect with electronics or signal processors. Some biosensors can be integrated with electronics; and thus, such biosensors may be considered electronic biosensors.

In general, the efficacy of biosensors can be improved.

### SUMMARY

Described herein are improved biosensors and methods thereof. Also, described herein are methods for sensing a biomarker which carries a net charge (e.g., a protein, a peptide, a bacteria, a virus, an antigen, or an antibody). Such sensors and methods can rapidly and accurately assess a disease state of a person. The disease state can be an infection that affects a population (e.g., a virus) or a particular biomarker for disease diagnosis (such as for cancer). Some embodiments can include a method to convert the output of the biosensors into electronic signals making the output of the sensors amenable for further electronic signal processing, transmission and storage. Such technologies can improve the analysis and understanding of disease spread and improve identification of hot spots.

In some embodiments, a system includes an electronic biosensor as well as a biomarker, a recognition motif, an anti-Debye screening layer, and a charge sensing layer. In such embodiments, the biosensor implements decoupled charge-based sensing and Debye screening. And, in such embodiments, the electronic biosensor includes the recognition motif, the anti-Debye screening layer, and the charge sensing layer. Some embodiments include a method implemented by such a system. Some embodiments includes a device including a recognition motif, an anti-Debye screening layer, and a charge sensing layer. In such embodiments, the recognition motif receives a biomarker which allows the device to sense the biomarker, and the device implements decoupled charge-based sensing and Debye screening.

In some embodiments, a system includes an anti-Debye screening layer and a charge sensing layer. The anti-Debye screening layer and the charge sensing layer are parts of a biosensor. The anti-Debye screening layer includes non-ionic hydrophilic compounds. In some embodiments, the system includes a recognition motif. In some embodiments, the recognition motif includes an antibody. In some embodiments, the recognition motif includes a deoxyribonucleic acid (DNA) aptamer. In some embodiments, the recognition motif includes a ribonucleic acid (RNA) aptamer.

In some embodiments, the system includes a homing device configured to operate with the recognition motif. In some embodiments, the homing device includes a magnetic nanoparticle. In some embodiments, the homing device includes a dielectric particle.

In some embodiments, the system includes a passivation layer adjoining the anti-Debye screening layer. In some embodiments, the charge sensing layer includes an open-gate metal oxide semiconductor field effect transistor (MOSFET), and the open-gate MOSFET interfaces the passivation layer and the anti-Debye screening layer, and the open-gate MOSFET includes N-type metal-oxide-semiconductor (NMOS) logic. In some embodiments, the charge sensing layer includes an open-gate MOSFET, and the open-gate MOSFET interfaces the passivation layer and the anti-Debye screening layer, and the open-gate MOSFET includes P-type metal-oxide-semiconductor (PMOS) logic.

In some embodiments, the anti-Debye screening layer includes a linear non-ionic polymer chain. In some embodiments, the anti-Debye screening layer includes branched polyols. In some embodiments, the anti-Debye screening layer includes trehalose.

In some embodiments, the charge sensing layer includes a charge sensor that includes a metal oxide semiconductor (MOS) capacitor. In some embodiments, the charge sensing layer includes a charge sensor that includes a high-electron-mobility transistor (HEMT). In some embodiments, the charge sensing layer includes a charge sensor that includes a complementary metal oxide semiconductor (CMOS) gate field effect transistor.

In some embodiments, a system includes an anti-Debye screening layer and a charge sensing layer including an open-gate MOSFET. In such embodiments, the anti-Debye screening layer and the charge sensing layer are parts of a biosensor, and the anti-Debye screening layer includes a linear non-ionic polymer chain, branched polyols, or trehalose. In some embodiments, the system includes a passivation layer adjoining the anti-Debye screening layer and interfacing the open-gate MOSFET.

In some embodiments, a system includes an anti-Debye screening layer, an open-gate MOSFET, and a recognition motif. In such embodiments, the anti-Debye screening layer, the open-gate MOSFET, and the recognition motif are parts of a biosensor, and the anti-Debye screening layer includes a linear non-ionic polymer chain, branched polyols, or trehalose.

In summary, the systems, devices, and methods (or techniques) disclosed herein can provide specific technical solutions to at least overcome the technical problems mentioned in other parts of the application as well as other technical problems not described herein but recognized by those skilled in the art.

These and other important aspects of the invention are described more fully in the detailed description below. The invention is not limited to the particular assemblies, apparatuses, methods and systems described herein. Other embodiments can be used and changes to the described embodiments can be made without departing from the scope of the claims that follow the detailed description.

### BRIEF DESCRIPTION OF THE DRAWINGS

The present disclosure will be understood more fully from the detailed description given below and from the accompanying drawings of various embodiments of the disclosure. It is to be understood that the accompanying drawings presented are intended for the purpose of illustration and not intended to restrict the disclosure.

FIG. 1 illustrates aspects of a biosensor, in accordance with some embodiments of the present disclosure.

FIG. 2 illustrates aspects of another biosensor, in accordance with some embodiments of the present disclosure.

FIG. 3 illustrates a method implemented by some of the systems described herein, in accordance with some embodiments of the present disclosure.

FIG. 4 illustrates is a block diagram of example aspects of an example computing system, in accordance with some embodiments of the present disclosure.

### DETAILED DESCRIPTION

Described herein are improved systems, devices and methods for overcoming technical problems associated with biosensors. Also, described herein are methods for sensing a biomarker which carries a net charge (e.g., a protein, a peptide, a bacteria, a virus, an antigen, or an antibody). Such sensors and methods can rapidly and accurately assess disease state of a person. The disease state can be a general infection that affects a population (e.g., a virus) or a particular biomarker for disease diagnosis (such as for cancer). Some embodiments can include a method to convert the output of the biosensors into electronic signals making the output of the sensors amenable for further electronic signal processing, transmission and storage. Such technologies can improve the analysis and understanding of disease spread and improve identification of hot spots.

The technical solutions described herein overcome the Debye screening effect that plagues current field effect transistor (FET) based sensors. The techniques can separate analyte recognition and signal transduction. And, the techniques can avoid immobilization of the recognition motif on the sensing area. The avoidance of immobilization of the recognition motif on the sensing area can prevent issues associated with orientation for molecular recognition. This can reduce fabrication cost and improve reliability of biosensors. Also, such technologies provide for the charged biomarker to be brought close to the sensing surface by applying an attractive force thereby decoupling sensing and recognition. This can allow for single molecule sensing and not just ensembled averages.

Also, such technical solutions can include providing a quantitative measure by employing thousands of miniature parallel sensors rather than one large sensor enabling quantitative particle counting and improving the limit of detection by reducing the capacitance of the sensing area. The solutions can also convert measurements into electronic signals enabling signal processing and artificial intelligence (AI) based recognition of molecular signatures. The solutions can also provide for transmission of results of sensing and further data processing as well as electronic recordings of the output signals to improve the study of disease progression and remission.

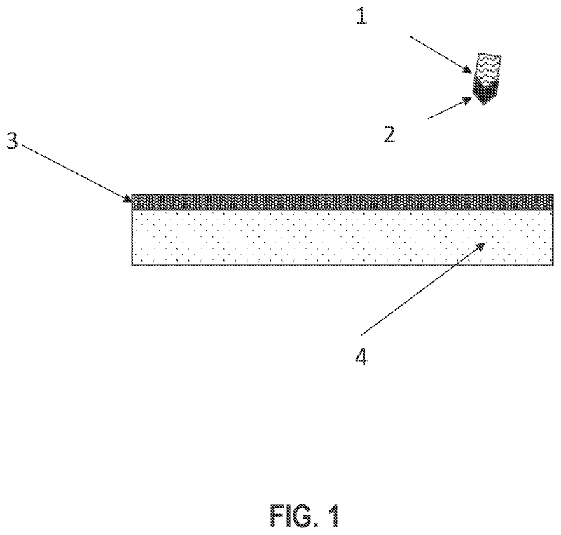

FIG. 1 illustrates aspects of an example electronic biosensor and related systems and methods, in accordance with some embodiments of the present disclosure. FIG. 1 shows a biomarker 1, a recognition motif 2, an anti-Debye screening layer 3, and a charge sensing layer 4. The recognition motif 2 can be an antibody in some embodiments or any other type of biomarker which carries a net charge in some other embodiments. And, the recognition motif 2 can be conjugated to a homing sensor in some embodiments. As shown the anti-Debye screening layer 3 can adjoin the charge sensing layer 4. The charge sensing layer 4 can include or be a complementary metal oxide semiconductor (CMOS) gate.

The electronic biosensor can include three parts including a recognition motif such as shown by recognition motif 2. In some embodiments, the recognition motif can include an antibody, DNA or RNA aptamer, or supramolecular assemblies. The recognition motif can be associated with or operable with or conjugated with a homing device such as a magnetic nanoparticle or dielectric particle. The three major parts can also include an anti-Debye screening layer such as shown by the anti-Debye screening layer 3. The anti-Debye screening layer can include polyethylene glycol or another type of linear non-ionic polymer chain (such as polymethyloxazoline). In some embodiments, the anti-Debye screening layer can include branched polyols or trehalose. The three major parts can also include a charge sensor such as shown by the charge sensing layer 4. The charge sensor can include a CMOS open gate field effect transistor, a MOS capacitor, or a high-electron-mobility transistor (HEMT).

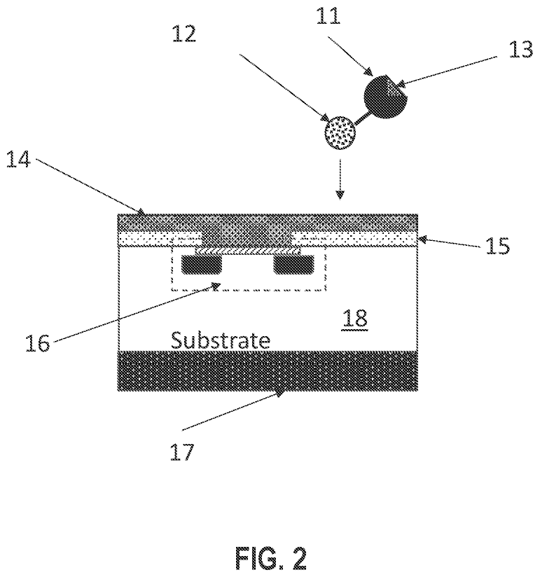

FIG. 2 also illustrates aspects of an example electronic biosensor and related systems and methods, in accordance with some embodiments of the present disclosure. And, similar to FIG. 1, FIG. 2 shows physical structures and combinations related to embodiments disclosed herein. FIG. 2 shows an example biosensor that can be an example of the biosensor shown in FIG. 1, in accordance with some embodiments of the present disclosure. FIG. 2 also shows examples methods and systems related to such biosensors, in accordance with some embodiments of the present disclosure.

FIG. 2 shows an antibody 11 connected with a magnetic nanoparticle 12 and an antigen 13. The antibody 11 provides an interface for the magnetic nanoparticle 12 and the antigen 13. The antigen 13 is a biomarker sensed by the electronic biosensor via the antibody 11 and magnetic nanoparticle 12. Also, shown is an anti-Debye screening layer 14 which can be similar to the anti-Debye screening layer 3. As shown the anti-Debye screening layer 14 adjoins a passivation layer 15. The passivation layer 15 can define a microfluidic well. In other words, the passivation layer 15 can be or include a microfluidic well defining layer.

The device can also include, as shown, an open-gate metal oxide semiconductor field effect transistor (MOSFET) 16. As shown, the open-gate MOSFET 16 can interface the passivation layer 15 as well as the anti-Debye screening layer 14. The open-gate MOSFET 16 can be or include P-type metal-oxide-semiconductor logic (PMOS) or N-type metal-oxide-semiconductor logic (NMOS) and can be fabricated from known CMOS fabrication processes. As a PMOS, the MOSFET 16 can be constructed using metal-oxide-semiconductor field effect transistor with a p-type semiconductor source and drain printed on a bulk n-type well. As an NMOS, the MOSFET 16 can operate by creating an inversion layer in a p-type transistor body. The inversion layer, or otherwise known as the n-channel, can conduct electrons between n-type source and drain terminals. The n-channel can be created by applying voltage to a third terminal, known as the gate. The PMOS and NMOS examples can have four modes of operation: cut-off (or subthreshold), triode, saturation (sometimes called active), and velocity saturation.

As shown, the open-gate MOSFET 16 is separated from a magnetic layer or magnet 17 by a semiconductor substrate layer 18. The MOSFET 16 can be a part of and/or formed in the semiconductor substrate layer 18. The substrate layer 18 can be or include silicon. The magnet 17 can be or include neodymium.

Some embodiments can use a foundry CMOS process with an open-gate accessible via a passivation cut either through metallized vias or a direct etch to the gate electrode. A microfluidic channel can be integrated on top of a CMOS chip via standard lithographic techniques. The opening can then be covered with a polymer coating including of polyethylene glycol (PEG) or another type of a linear non-ionic polymer chain (such as polymethyloxazoline). Also, the opening can be covered with polyols (e.g., trehalose).

The microfluidic channel can be some distance away from the sensing region and can be partially filled with a stabilized recognition motif conjugated with a homing device. For example, a polyol stabilized antibody can be conjugated with a magnetic nanoparticle. When a solution containing the biomarker is introduced into the channel, it can react with the recognition motif in the microfluidic channel. The reaction time can be tailored by adjusting the length of the channel. After a sufficient duration, an attractive force can be applied (such as by magnetic field though a magnet or coil) to bring the complex (including the stabilized recognition motif conjugated with a homing device) to the sensing region.

As shown, the novel devices described herein can implement or be a part of novel systems and methods.

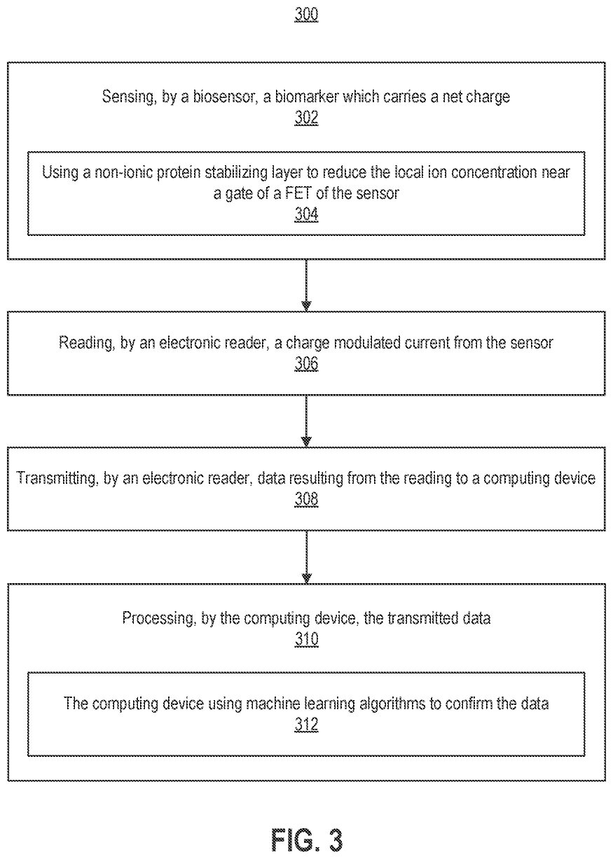

In some embodiments, an electronic method can be implemented for sensing a biomarker which carries a net charge (e.g., a protein, a peptide, a bacteria, a virus, an antigen, an antibody, etc.). The sensors can be based on a FET. The sensing of charged objects using a FET can be implemented by sensing the change in charge that occurs when a charged object is brought in the vicinity of a FET, such as an open gate FET. E.g., see step 302 of method 300 shown in FIG. 3. The charged object induces charges on the semiconductor layer which can be readout as a change on the FET drain current. Such a technique can be implemented using ion-sensitive field effect transistors (ISFETs) for sensing pH.

Unlike sensing pH, which can be intrinsically sensed by the protonation and/or deprotonation at the gate oxide of the metal-oxide-semiconductor (MOS), sensing of molecules can occur through a recognition layer. In such embodiments, the recognition layer can have an intrinsic issue, which can include the thickness of the recognition layer being many orders of magnitude larger than the charge screening length set by the ionic concentration of the sample. While such an issue in sensing of inorganic molecules can be overcome by lowering the background ion concentration of the sample by dilution, biological molecules may depend on the background ionic concentration to maintain their proper folded shape. Thus, a recognition layer can implement a tradeoff making the direct application of the MOSFET to biological sensing challenging. For example, an antibody for biological sensing and the sensor, called an immunoFET, can have problems. This type of sensing should not be confused with nanowire FET devices or organic FET devices which modulate the substrate conductivity upon recognition. The approach does not leverage the intrinsic gain of the saturated MOSFET and usually operates in the linear regime resulting in lower sensitivity.

An associated issue of using biological entities as recognition elements is a recognition element needs to be bound to the gate of the transistor to effectively transduce the change in charge upon recognition to the semiconductor substrate via the field effect. This is especially the case if the recognition element is an antibody which requires a certain orientation for proper binding. However, surface immobilization reduces the degrees of freedom of the antibody and may not result in recognition of the biomolecule.

In exemplary embodiments, the devices, methods, and systems disclosed herein resolve (at least partially) the aforesaid problems. Such exemplary embodiments can use non-ionic hydrophilic compounds in a stabilizing layer. Also, embodiments can use a non-ionic protein stabilizing layer made of unmodified or modified naturally occurring substrates. This is what is shown in FIGS. 1 and 2, and at step 304 shown in FIG. 3. The presence of this layer effectively reduces the local ion concentration near the gate of the MOSFET thereby overcoming the screening effect imposed by the Debye layer; and thus, is referred to herein as an anti-Debye screening layer (e.g., see FIGS. 1 and 2 and corresponding text). Some embodiments can use PEG or another type of a linear non-ionic polymer chain (such as polymethyloxazoline). And, some of such embodiments can use the chain with nanowire FETs. PEG is a known antifouling agent and can prevent protein adsorption as well as hinder the approach of the biomolecule to the surface. Non-ionic hydrophilic compounds on the other hand help proteins maintain their shape even in extreme conditions of heat and desiccation. In some embodiments of the device, the layer, including non-ionic hydrophilic compounds, is applied as a thin gel layer on top of the open MOSFET gate. The molecule can also be tethered to the gate via molecular tethering using salinization or thiol conjugation.

Relative to approaches using FET based sensing, exemplary embodiments do not immobilize the recognition molecule on the surface. Instead, such embodiments attach the recognition molecule (e.g., the antibody 11) to a magnetic nanoparticle (e.g., a nanoparticle having a diameter of 10-50 nm) via a tether (e.g., see magnetic nanoparticle 12). In some exemplary embodiments of the device, the antibody conjugated nanoparticle is placed in a microchannel with or without stabilizing compounds (e.g., polyols). The microfluidic channel is designed to bring the sample to the vicinity of the MOSFET. The sample is introduced into the channels and flows towards the MOSFET and is allowed to interact with the antibody. The length of the channel is designed to enable adequate incubation time for molecular recognition of the analyte by the sensor conjugated nanoparticle.

In some embodiments, the channel terminates at the MOSFET, which can be coated with non-ionic hydrophilic compounds, while the flow of the channel ensures the particle approaches the vicinity of the gate. For sensing to occur the complex (including the particle) has to be brought close to the surface of the transistor. To ensure sensing, a magnetic force can be applied via a permanent magnet (e.g., a neodymium magnet) to attract the particle to the surface of the MOSFET. The distance of the particle to the surface is governed by the total size of the complex if adequate magnetic force is applied.

Another aspect of the device is to use multiple transistors to cover a large area rather than a single MOSFET. Current MOSFET devices are as small as 5 nm but an exemplary technology node for some embodiments is 65 nm. This segmenting with individual drain current sensing enables high sensitivity and allows particle counting, which allows a quantitative measure and not only a qualitative answer.

In some embodiments, an additional dummy channel containing only the recognition motif and homing device in the appropriate solution is incorporated enabling differential measurements.

In some embodiments of the device, the magnetic field is applied and removed periodically and the time of flight between application of the force can give an estimate of the size of the particle by using a diffusion equation. This enables another level of specificity.

Some embodiments include an electronic reader. In such embodiments, the reader is a smartphone or a computer. It can also be a standalone device with the necessary electronics. The device reads the charge modulated current from the biosensor and transmits the data to a hub or smartphone. E.g., see steps 306 and 308 of method 300 shown in FIG. 3. The data is then processed, and the results can be displayed and stored on the reader. E.g., see step 310 of method 300 shown in FIG. 3.

In some embodiments, the sensing device can be based on fluorescence and a zero-mode waveguide where the complex is brought to a well and interrogated with the zeroth mode of a light source by appropriately sizing the well. The resulting fluorescence can then be read. The attractive force can also be an optical tweezer that guides the complex.

Some embodiments can include a modular electronic reader. In some embodiments, the reader is a smartphone or a computer. It can also be a standalone device with the necessary electronics which can interface via networked connectivity with a computer or mobile device. The device reads the charge modulated current from the sensor and transmits the data to a hub or smart device. E.g., see steps 306 and 308 of method 300 shown in FIG. 3. The data is then processed, and the results displayed and stored on the reader locally, on a networked computing device or Internet-based data storage. E.g., see step 310 of method 300 shown in FIG. 3.

The electronic reader can include artificial intelligence and/or machine learning algorithms used to confirm the data. E.g., see step 312 of method 300 shown in FIG. 3. In some embodiments, such functions can be supported by signal processing circuitry wherein the post-processed data is compared and trained against a library of similar data, whether on the device, stored in memory or accessible via software communicating to an outside data server or database. The machine learning algorithm or AI can enhance speed and accuracy of data being read from the FET and can be used to build a library of data to identify data anomalies.

Also, a database can be generated from the data sets and the database can serve as a repository for cumulative data logs wherein future insight can be derived from such archives. Data conducive to patterning and epidemiological reporting of confirmed viral load count along with timestamping and supplemented by secondary geolocational and or demographic data is another feature that can be combined with embodiments mentioned herein.

With respect to some embodiments, disclosed herein are computerized methods combined with the improved biosensors for improved detection of disease and analysis of data related to disease, as well as a non-transitory computer-readable storage medium for carrying out technical operations of the computerized methods. The non-transitory computer-readable storage medium has tangibly stored thereon, or tangibly encoded thereon, computer readable instructions that when executed by one or more devices (e.g., one or more personal computers or servers) cause at least one processor to perform a method for a novel and improved detection of disease and analysis of data related to disease.

For example, FIG. 3, illustrates a method 300 implemented by some of the systems described herein, in accordance with some embodiments of the present disclosure. The method 300 commences, at step 302, with sensing, by a biosensor, a biomarker which carries a net charge (e.g., protein, peptide, bacteria, virus, antigen, antibody, etc.). The sensor can be based on a field effect transistor (FET). The sensing of charged objects using a FET can be implemented by sensing the change in charge that occurs when a charged object is brought in the vicinity of a FET, such as an open gate FET. The charged object induces charges on the semiconductor layer which can be readout as a change on the FET drain current.

The method 300 continues, at step 304, with using a non-ionic protein stabilizing layer to reduce the local ion concentration near the gate of the FET. The use of the non-ionic protein stabilizing layer at step 304 overcomes the screening effect imposed by the Debye layer. And, thus the layer is referred to herein as an anti-Debye screening layer.

The method 300 continues, at step 306, with an electronic reader reading a charge modulated current from the sensor. At step 308 of the method 300, the reader transmits data, resulting from the reading of the current, to a computing device (e.g., a hub or smartphone). At step 310 of the method 300, the computing device processes the transmitted data. The results of the processing can be displayed or stored by the reader, the computing device, a database, and/or one or more other devices.

The method 300 continues, at step 312, with the computing device using machine learning algorithms to confirm the data.

With respect to some embodiments, a system is provided that includes at least one computing device combined with the biosensor and configured to provide detection of disease and analysis of data related to disease. And, with respect to some embodiments, a method is provided to be performed by at least one computing device. In some example embodiments, computer program code can be executed by at least one processor of one or more computing devices to implement functionality in accordance with at least some embodiments described herein; and the computer program code being at least a part of or stored in a non-transitory computer-readable medium.

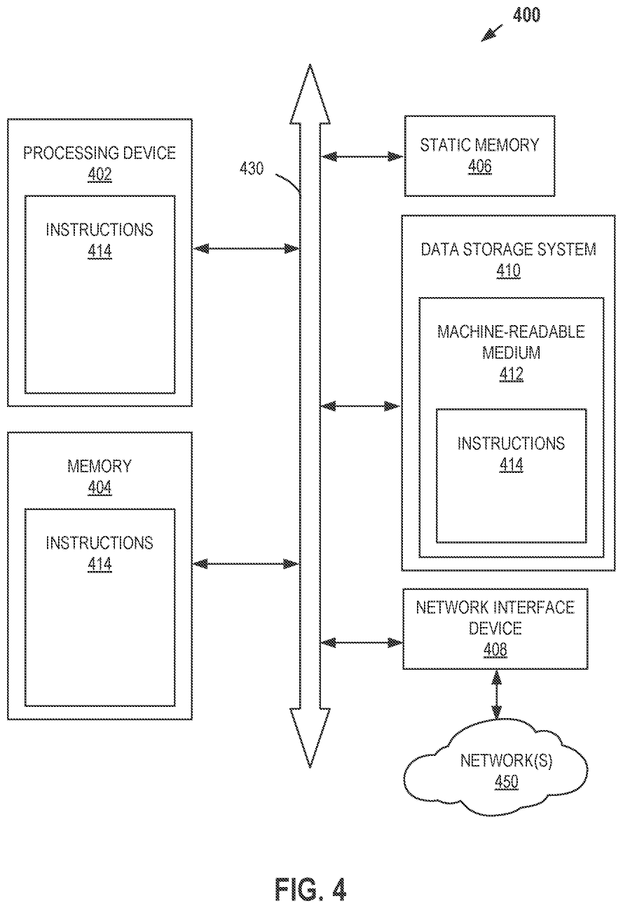

FIG. 4 illustrates is a block diagram of example aspects of an example computing system 400, in accordance with some embodiments of the present disclosure. FIG. 4 illustrates parts of the computing system 400 within which a set of instructions, for causing a machine of the computing system 400 to perform any one or more of the methodologies performed by a computing device discussed herein, can be executed (such as some of the operations of method 300). In some embodiments, the computing system 400 can correspond to a host system that includes, is coupled to, or utilizes memory or can be used to perform the operations of a controller. In alternative embodiments, the machine can be connected (e.g., networked) to other machines in a LAN, an intranet, an extranet, and/or the Internet.

The machine can operate in the capacity of a server or a client machine in client-server network environment, as a peer machine in a peer-to-peer (or distributed) network environment, or as a server or a client machine in a cloud computing infrastructure or environment. The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies performed by a computing device discussed herein (such as some of the operations of method 300).

The computing system 400 includes a processing device 402, a main memory 404 (e.g., read-only memory (ROM), flash memory, dynamic random-access memory (DRAM), etc.), a static memory 406 (e.g., flash memory, static random-access memory (SRAM), etc.), and a data storage system 410, which communicate with each other via a bus 430. The processing device 402 represents one or more general-purpose processing devices such as a microprocessor, a central processing unit, or the like. More particularly, the processing device can be a microprocessor or a processor implementing other instruction sets, or processors implementing a combination of instruction sets. The processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 414 for performing the operations discussed herein.

The computing system 400 can further include a network interface device 408 to communicate over one or more LAN/WAN networks 450. The LAN/WAN network(s) 450 can include one or more local area networks (LAN(s)) and/or one or more wide area networks (WAN(s)). The LAN/WAN network(s) 450 can include the Internet and/or any other type of interconnected communications network. The LAN/WAN network(s) 450 can also include a single computer network or a telecommunications network. More specifically, the LAN/WAN network(s) 450 can include a local area network (LAN) such as a private computer network that connects computers in small physical areas, a wide area network (WAN) to connect computers located in different geographical locations, and/or a metropolitan area network (MAN)—also known as a middle area network—to connect computers in a geographic area larger than that covered by a large LAN but smaller than the area covered by a WAN.

The data storage system 410 can include a machine-readable storage medium 412 (also known as a computer-readable medium) on which is stored one or more sets of instructions 414 or software embodying any one or more of the methodologies or functions described herein. The instructions 414 can also reside, completely or at least partially, within the main memory 404 and/or within the processing device 402 during execution thereof by the computing system 400, the main memory 404 and the processing device 402 also constituting machine-readable storage media.

In some embodiments, the instructions 414 include instructions to implement functionality corresponding to one or more of steps 306, 308, 310, and 312 of method 300. While the machine-readable storage medium 412 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure performed by a computing system or computing device. The term “machine-readable storage medium” shall accordingly be taken to include, but not be limited to, solid-state memories, optical media, and magnetic media.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system, comprising:
an anti-Debye screening layer; and
a charge sensing layer,
wherein the anti-Debye screening layer and the charge sensing layer are parts of a biosensor, and
wherein the anti-Debye screening layer comprises non-ionic hydrophilic compounds.

2. The system of claim 1, further comprising a recognition motif.

3. The system of claim 2, wherein the recognition motif comprises an antibody.

4. The system of claim 2, wherein the recognition motif comprises deoxyribonucleic acid (DNA) aptamer.

5. The system of claim 2, wherein the recognition motif comprises a ribonucleic acid (RNA) aptamer.

6. The system of claim 2, further comprising a homing device configured to operate with the recognition motif.

7. The system of claim 6, wherein the homing device comprises a magnetic nanoparticle.

8. The system of claim 6, wherein the homing device comprises a dielectric particle.

9. The system of claim 1, further comprising a passivation layer adjoining the anti-Debye screening layer.

10. The system of claim 9,
wherein the charge sensing layer comprises an open-gate metal oxide semiconductor field effect transistor (MOSFET),
wherein the open-gate MOSFET interfaces the passivation layer and the anti-Debye screening layer, and
wherein the open-gate MOSFET comprises N-type metal-oxide-semiconductor (NMOS) logic.

11. The system of claim 9,
wherein the charge sensing layer comprises an open-gate metal oxide semiconductor field effect transistor (MOSFET),
wherein the open-gate MOSFET interfaces the passivation layer and the anti-Debye screening layer, and
wherein the open-gate MOSFET comprises P-type metal-oxide-semiconductor (PMOS) logic.

12. The system of claim 1, wherein the anti-Debye screening layer comprises a linear non-ionic polymer chain.

13. The system of claim 1, wherein the anti-Debye screening layer comprises branched polyols.

14. The system of claim 1, wherein the anti-Debye screening layer comprises trehalose.

15. The system of claim 1, wherein the charge sensing layer comprises a charge sensor that comprises a metal oxide semiconductor (MOS) capacitor.

16. The system of claim 1, wherein the charge sensing layer comprises a charge sensor that comprises a high-electron-mobility transistor (HEMT).

17. The system of claim 1, wherein the charge sensing layer comprises a charge sensor that comprises a complementary metal oxide semiconductor (CMOS) gate field effect transistor.

18. A system, comprising:
an anti-Debye screening layer; and
a charge sensing layer comprising an open-gate metal oxide semiconductor field effect transistor (MOSFET),
wherein the anti-Debye screening layer and the charge sensing layer are parts of a biosensor, and
wherein the anti-Debye screening layer comprises a linear non-ionic polymer chain, branched polyols, or trehalose.

19. The system of claim 18, further comprising a passivation layer adjoining the anti-Debye screening layer and interfacing the open-gate MOSFET.

20. A system, comprising:
an anti-Debye screening layer;
an open-gate metal oxide semiconductor field effect transistor (MOSFET); and
a recognition motif,
wherein the anti-Debye screening layer, the open-gate MOSFET, and the recognition motif are parts of a biosensor, and
wherein the anti-Debye screening layer comprises a linear non-ionic polymer chain, branched polyols, or trehalose.
